(19) United States
(12) Patent Application Publication
(10) Pub. No.: US 2026/0247879 A1
(43) Pub. Date: Aug. 20, 2026

(54) METHOD OF FORMING THIN FILM AND METHOD OF MANUFACTURING INTEGRATED CIRCUIT DEVICE BY USING THE THIN FILM

(71) Applicant: Samsung Electronics Co., Ltd., Suwon-si (KR)

(72) Inventors: Jaewoon Kim, Suwon-si (KR); Gyuhee Park, Suwon-si (KR); Jeongho Kim, Suwon-si (KR); Heejin Do, Suwon-si (KR); Haneul Yang, Suwon-si (KR); Yunho Lee, Suwon-si (KR); Younjoung Cho, Suwon-si (KR); Junyeong Jo, Suwon-si (KR); Jinwoo Choi, Suwon-si (KR); Sangjun Yim, Suwon-si (KR); Byeongok Cho, Suwon-si (KR)

(73) Assignee: Wonik Materials, Chungcheongbuk-do (KR)

(21) Appl. No.: 19/327,970

(22) Filed: Sep. 12, 2025

(30) Foreign Application Priority Data
Feb. 18, 2025 (KR) 10-2025-0020969

(51) Int. Cl. H01L 21/3205; C23C 16/44; C23C 16/455; H01L 21/321

(52) U.S. Cl. CPC H10P 14/412; C23C 16/4408; C23C 16/45527; C23C 16/45553; H10P 95/00

(57) ABSTRACT

Provided are methods of forming a high-purity ruthenium-containing thin film in each of a non-oxidation condition and an oxidation condition, and a method of manufacturing an integrated circuit device having improved electrical reliability by using the high-purity ruthenium-containing thin film. The thin films may be deposited using a ruthenium compound including hfac.

### CROSS-REFERENCE TO RELATED APPLICATION

This application claims priority under 35 U.S.C. § 119 to Korean Patent Application No. 10-2025-0020969, filed on Feb. 18, 2025, in the Korean Intellectual Property Office, the entirety of which is incorporated by reference herein.

### BACKGROUND

Due to the advancement of electronics technology, integrated circuit devices have been rapidly down-scaled in recent years, and thus, patterns constituting electronic devices have been micronized. Therefore, it is necessary to develop a raw material compound for metal-containing film formation, the raw material compound being easy-to-handle, having good effects in process stability and mass productivity, and being capable of providing excellent properties in filling and step coverage during the formation of a metal-containing film required for manufacturing an integrated circuit device.

### SUMMARY

Ruthenium is a low-resistance metal material. Some aspects of this disclosure provide methods for introducing ruthenium into semiconductor processes.

Some aspects of this disclosure provide methods of forming a high-purity ruthenium-containing thin film in each of a non-oxidation condition and an oxidation condition.

Some aspects of this disclosure provide methods of manufacturing an integrated circuit device, which may provide intended electrical characteristics, by using the high-purity ruthenium-containing thin film.

Other contributions and aspects of the present disclosure will be clearly understood by those of ordinary skill in the art from the following description.

According to some implementations of the present disclosure, there is provided a method of forming a thin film, the method including forming a ruthenium thin film by supplying a reaction gas and a precursor compound onto a first region of a substrate, and supplying a purge gas onto the substrate, wherein the precursor compound includes a ruthenium compound represented by Chemical Formula 1 shown below, and in Chemical Formula 1, L¹ is a bidentate ligand.

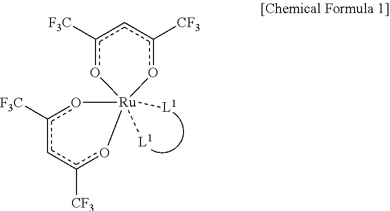

According to some implementations of the present disclosure, there is provided a method of forming a thin film, the method including forming a ruthenium thin-film by supplying a reaction gas and a precursor compound onto a first region of a substrate, and supplying a purge gas onto the substrate, wherein the precursor compound includes a ruthenium compound represented by Formula 2 shown below, and in Chemical Formula 2, L² is a coordination ligand.

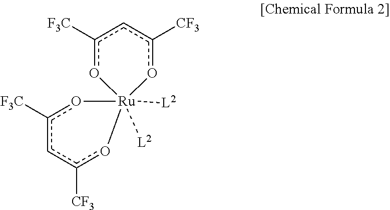

According to some implementations of the present disclosure, there is provided a method of forming a thin film, the method including forming a ruthenium thin film by supplying a reductive reaction gas and/or an oxidative reaction gas as well as a precursor compound onto a first region of a substrate, and supplying a purge gas onto the substrate, wherein the precursor compound includes at least one ruthenium compound selected from ruthenium compounds represented by Chemical Formulae 1 to 12 shown below and combinations thereof,

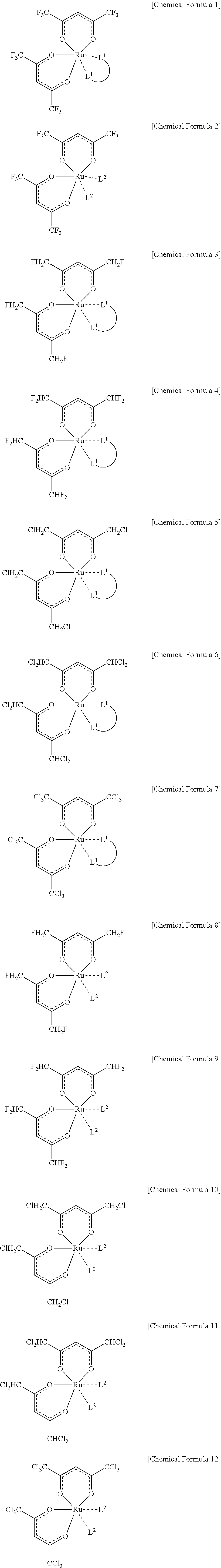

wherein, in Chemical Formulae 1, 3, 4, 5, 6, and 7, L¹ is a bidentate ligand, and in Chemical Formulae 2, 8, 9, 10, 11, and 12, L² is a coordination ligand.

### BRIEF DESCRIPTION OF THE DRAWINGS

FIG. 1 is a flowchart illustrating an example of a method of forming a ruthenium thin film;

FIG. 2 is a flowchart illustrating an example of a method of forming a ruthenium thin film; and

FIGS. 3, 4A, and 4B are schematic diagrams illustrating an example of a method of forming a ruthenium thin film.

### DETAILED DESCRIPTION

In the following description, like components are denoted by like reference numerals throughout the specification, and repeated descriptions thereof are omitted.

Certain examples are illustrated in the accompanying drawings and described in detail in the following detailed description. However, the scope of the present disclosure is not limited to the particular examples discussed below, and it should be understood that modifications, equivalents, and substituents of those examples fall within the scope of the present disclosure. When it is determined that specific descriptions of techniques known in the art may distract from the focus of the present application, such descriptions are omitted.

A ruthenium compound according to some implementations of the present disclosure may be represented by Chemical Formula 1 shown below.

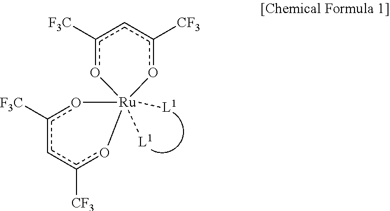

In Chemical Formula 1, L¹ may be a bidentate ligand. In some implementations, L¹ may be a diene, a diazadiene, an aminoether, or an allylamine. Specific examples of L¹ are described below.

The ruthenium compound according to some implementations of the present disclosure may be represented by Chemical Formula 2 shown below.

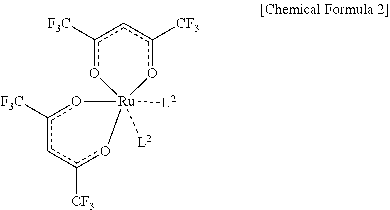

In Chemical Formula 2, L² may be a ligand. Specific examples of L² are described below.

The ruthenium compound represented by each of Formula 1 and Formula 2 may be used as a precursor for depositing a high-purity ruthenium thin film. The ruthenium compound may be a raw material for forming a ruthenium thin film. Herein, the ruthenium compound including the raw material for forming a ruthenium thin film may be referred to as a “ruthenium compound”.

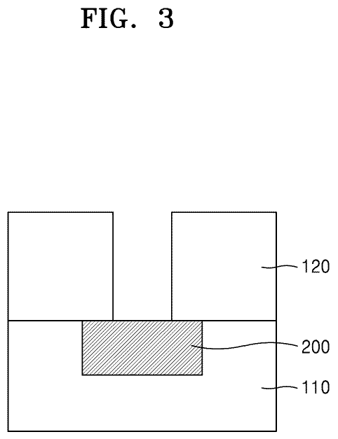

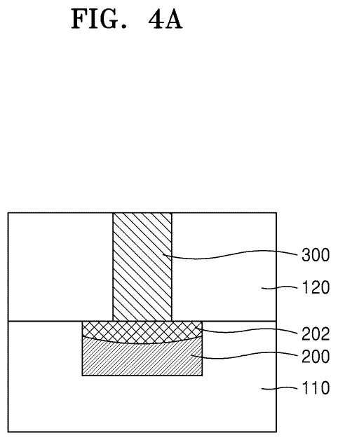

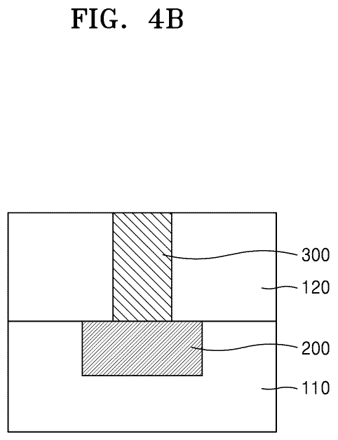

Using the ruthenium compounds, a ruthenium thin film having high-purity and low-resistance properties may be formed in a non-oxidation condition, and thus, the ruthenium thin film may have excellent mechanical reliability. In addition, when the ruthenium thin film deposited by using the ruthenium compound is introduced into a semiconductor manufacturing process, the reliability of a resulting semiconductor device may also improve. This is described in detail with reference to FIGS. 3, 4A, and 4B.

In addition, in some implementations, in an environment that is not a non-oxidation condition, for example, in an oxidation condition, a ruthenium thin film having high-purity and low-resistance properties may also be formed.

As described above, in the ruthenium compound represented by Chemical Formula 1, L¹ may be a diene, a diazadiene, an aminoether, or an allylamine, but L¹ is not limited thereto.

In some implementations, when L¹ includes a diene, L¹ may be represented by Chemical Formula 3 shown below.

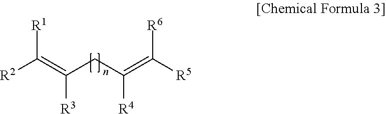

In some implementations, in Chemical Formula 3, n may be one of 0, 1, 2, 3, and 4, and each of R¹, R², R³, R⁴, R⁵, and R⁶ may be hydrogen or a structure including carbon. In addition, Chemical Formula 3 (e.g., R¹, R², R³, R⁴, R⁵, or R⁶) may include a heteroatom.

In some implementations, when L¹ includes a diazadiene, L¹ may be represented by Chemical Formula 4 shown below.

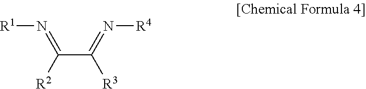

In some implementations, in Chemical Formula 4, each of R¹ and R⁴ may be a hydrocarbon, hydrogen, or a hydrocarbon including a heteroatom. In addition, each of R² and R³ may be hydrogen or carbon or may include a heteroatom.

In some implementations, when L¹ includes an aminoether, L¹ may be represented by Chemical Formula 5 shown below.

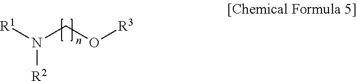

In some implementations, in Chemical Formula 5, n may be one of 1, 2, 3, and 4, and each of R¹, R², and R³ may be hydrogen or a structure including carbon. In addition, Chemical Formula 5 (e.g., R¹, R², or R³) may include a heteroatom.

In some implementations, when L¹ includes an allylamine, L¹ may be represented by Chemical Formula 6 shown below.

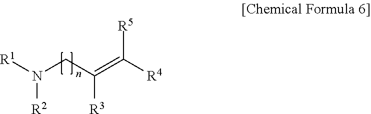

In some implementations, in Chemical Formula 6, n may be one of 1, 2, 3, and 4, and each of R¹, R², R³, R⁴, and R⁵ may be hydrogen or a structure including carbon. In addition, Chemical Formula 6 (e.g., R¹, R², R³, R⁴, or R⁵) may include a heteroatom.

As described above, in the ruthenium compound represented by Chemical Formula 2, L² may be represented by Formula 7 shown below, but L² is not limited thereto.

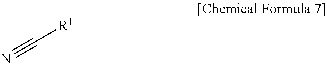

In some implementations, in Chemical Formula 7, R¹ may be a structure including carbon. In addition, Chemical Formula 7 (e.g., R¹) may include a heteroatom.

Specific examples of the ruthenium compounds are respectively represented by Formulae 1 to 30.

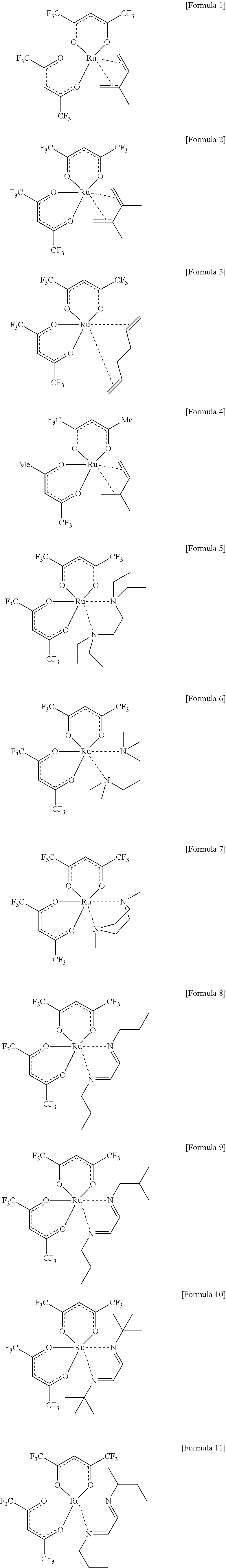

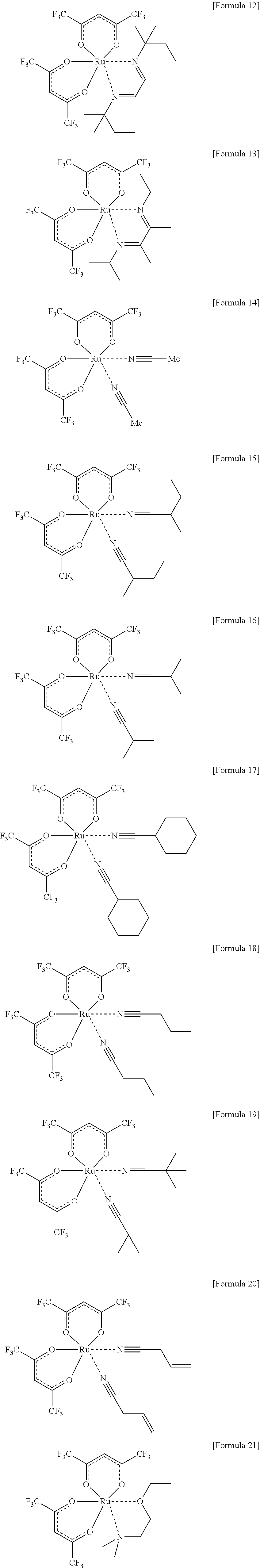

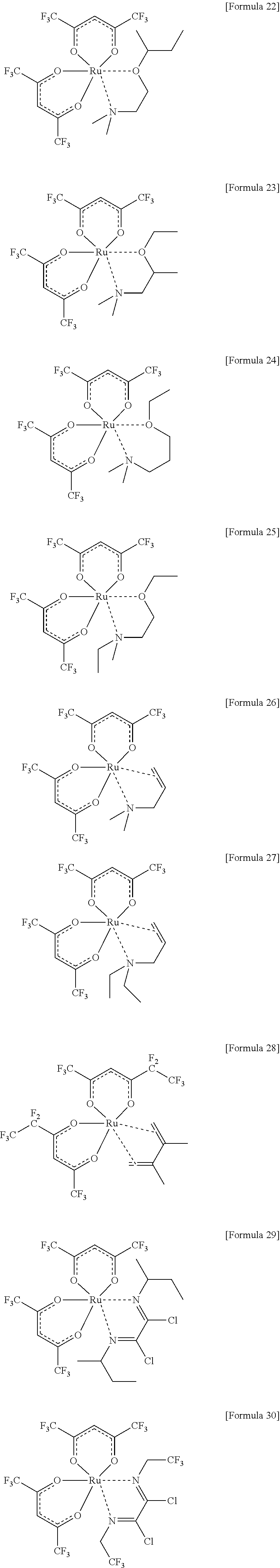

Methods of synthesizing the ruthenium compounds described herein are not particularly limited, and the ruthenium compounds may be synthesized by using reactions known in the art.

Referring to Formulae 1 to 30 shown above, Formulae 1 to 13 and Formulae 21 to 30 are examples falling within the structure represented by Chemical Formula 1, and Formulae 14 to 20 are examples falling within the structure represented by Chemical Formula 2.

In some implementations, the ruthenium compound may be represented by a structure other than Chemical Formula 1 described above.

For example, the ruthenium compound may be represented by Chemical Formula 8, 9, 10, 11, or 12.

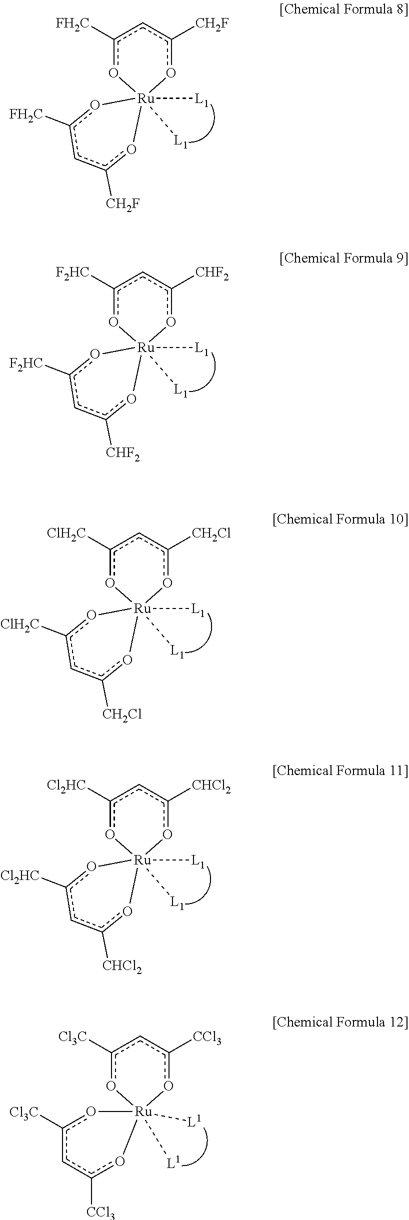

L¹ in Chemical Formulae 8 to 12 may be the same as described with reference to Chemical Formula 1. Each of the ruthenium compounds represented by Chemical Formulae 8 to 12 may have the same structure as Chemical Formula 1 except that each of the ruthenium compounds represented by Chemical Formulae 8 to 12 includes one of CH₂F, CHF₂, CH₂Cl, CHCl₂, and CCl₃ instead of CF₃ at the position of CF₃ in Chemical Formula 1.

In some implementations, the ruthenium compound may be represented by a structure other than Chemical Formula 2 described above.

For example, the ruthenium compound may be represented by Chemical Formula 13, 14, 15, 16, or 17.

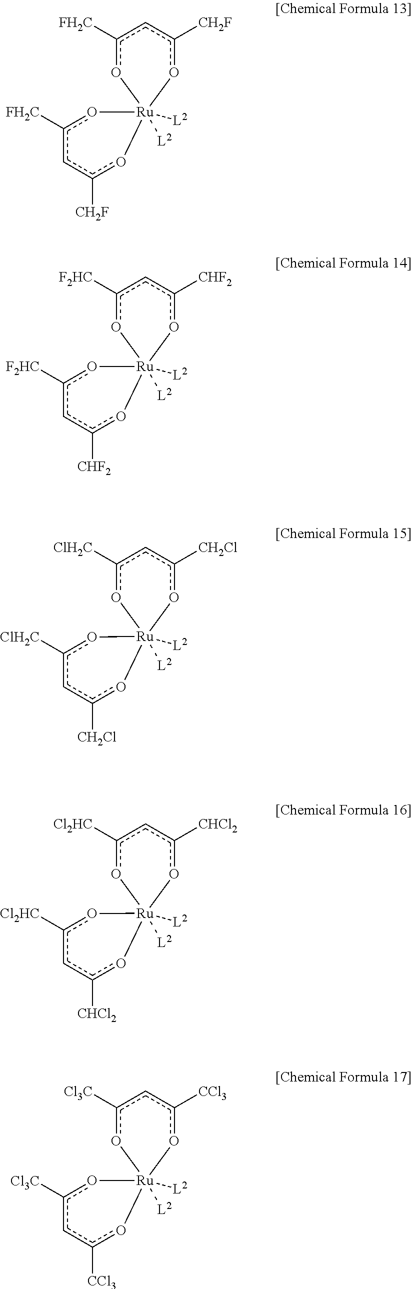

L² in Chemical Formulae 13 to 17 may be the same as described with reference to Chemical Formula 2. Each of the ruthenium compounds represented by Chemical Formulae 13 to 17 may have the same structure as Chemical Formula 2 except that each of the ruthenium compounds includes one of CH₂F, CHF₂, CH₃Cl, CHCl₂, and CCl₃ instead of CF₃ at the position of CF₃ in Chemical Formula 2.

The ruthenium compound may be a ruthenium compound including a hexafluoroacetylacetonate ligand (which may be referred to as an “hfac ligand”, hereinafter) that is a fluorine-containing diketonate ligand. In some implementations, because the ruthenium compound includes an hfac ligand, the ruthenium compound may have higher volatility and lower melting point than a ruthenium compound that includes a diketonate ligand including no hfac ligand, thereby exhibiting excellent properties as a material for chemical vapor deposition (CVD) or atomic layer deposition (ALD) processes described below.

In addition, because some implementations of the ruthenium compound does not require an oxidant, for example, O₂ gas, an oxygen-containing gas, or the like, as a reaction gas, when the surface of a metal on or over a substrate is exposed during the deposition of a thin film, the possibility of deteriorating a device due to the oxidation of the metal may be reduced or prevented. Because some implementations of the ruthenium compound includes an hfac ligand, a reductive gas, for example, NH₃ gas, an NH₃-containing gas, or the like, is used, and thus, a high-purity low-resistance ruthenium thin film may be obtained while the oxidation of a metal is prevented.

In addition, the ruthenium compounds provided herein can provide effective deposition in oxidizing environments. For example, even in an environment including an oxidative gas as a reaction gas, a high-purity low-resistance ruthenium thin film may be formed.

It is noted that Chemical Formulae 8 to 17 may lack hfac. However, Chemical Formulae 8 to 17 include ligands that may provide similar advantages to hfac, e.g., with CF₃ in hfac replaced by another compound such as CH₂F, CHF₂, CH₃Cl, CHCl₂, or CCl₃. As such, references herein to the advantages provided by hfac and hfac-containing ruthenium compounds may apply also to these alternative ligands and ruthenium compounds. Accordingly, references to these other ligands may be omitted below, and references to hfac and hfac-including compounds should be understood to also encompass these alternative ligands except where suggested otherwise by context.

Hereinafter, properties of ruthenium compounds including an hfac ligand are described in detail with reference to Table 1.

TABLE 1

| | | | Comparative | Comparative |
|---|---|---|---|---|
| | Example 1 | Example 2 | Example 1 | Example 2 |
| Molecular | 583.29 | 597.32 | 367.41 | 381.44 |
| weight | | | | |
| State | Solid | Liquid | Solid | Solid |
| Melting point | 43 | — | 90 | 90 |
| (° C.) | | | | |
| Volatility (° C.) | 165 | 174 | 245 | — |

The “Volatility (° C.)” in Table 1 corresponds to a “thermogravimetric analysis (TGA)-weight 50% reduction temperature (° C.)”.

Example 1, Example 2, Comparative Example 1, and Comparative Example 2 in Table 1 have the following structural formulae, respectively.

### Example 1

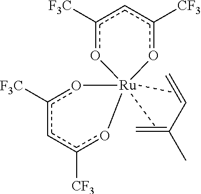

### Example 2

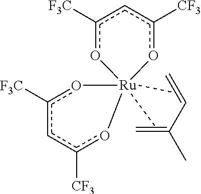

### Comparative Example 1

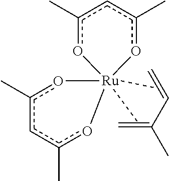

### Comparative Example 2

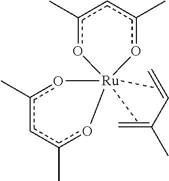

Each of Example 1 and Example 2 correspond to a ruthenium compound including an hfac ligand, and each of Comparative Example 1 and Comparative Example 2 correspond to a ruthenium compound including no hfac ligand.

Referring to Table 1 together with the structural formulae of Example 1, Example 2, Comparative Example 1, and Comparative Example 2, although Example 1 and Example 2 each including an hfac ligand were respectively identified as a solid having a melting point of 43° C. and a liquid having a melting point less than room temperature, Comparative Example 1 and Comparative Example 2 each including an acetylacetonate ligand (which may be referred to as an “acac ligand”, hereinafter) without including an hfac ligand were identified to have a melting point of 90° C.

In addition, because it was observed that, while Example 1 and Example 2 respectively have TGA-weight 50% reduction temperatures of 165° C. and 174° C., Comparative Example 1 has a TGA-weight 50% reduction temperature of 245° C., it may be confirmed that the ruthenium compound including an hfac ligand is easily volatilized at a lower temperature than the ruthenium compound including an acac ligand.

That is, in some implementations, because the ruthenium compound according to the includes an hfac ligand, the melting point thereof may be less than 40° C., and the TGA-weight 50% reduction temperature thereof may be less than 245° C.

In addition, an experiment of forming a ruthenium thin film at a chamber temperature of 45° C. and a process pressure of 7 Torr by using the ruthenium compound according to Example 1 was performed. Here, a CVD process was performed by using a Si substrate including SiO₂ having a thickness of 1000 Å as a substrate for ruthenium thin film deposition and using NH₃ gas as a reaction gas, thereby forming the ruthenium thin film having a thickness of 30.8 nm. Specifically, while NH₃ gas was supplied at 1500 sccm for 1 minute, the substrate was stabilized such that the substrate reaches a sufficient temperature, followed by simultaneously introducing a ruthenium compound precursor according to Example 1 and the reaction gas (NH₃ gas) into a chamber, thereby forming the ruthenium thin film. Here, argon was introduced as a carrier gas at 60 sccm into the chamber, and NH₃ gas, which is a reaction gas, was introduced at 1500 sccm into the chamber. The temperature of the substrate during deposition was 450° C. As a result of forming the ruthenium thin film having a thickness of 30.8 nm according to the process conditions set forth above, the resistivity of the ruthenium thin film was observed to be about 10.6u Q*cm, and thus, it was confirmed that the ruthenium having low resistance may be obtained when the ruthenium compound including an hfac ligand is used as a precursor for the ruthenium thin film.

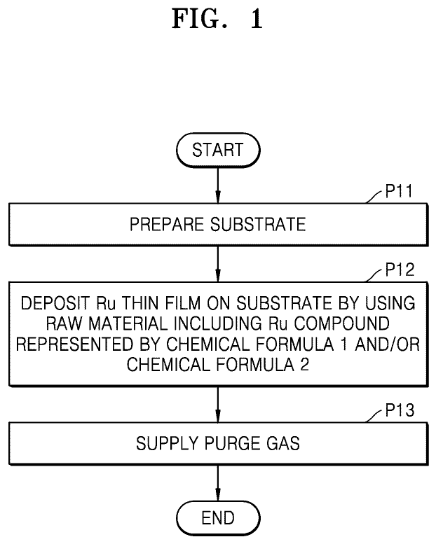

FIG. 1 is a flowchart illustrating an example of a method of forming a ruthenium thin film.

Referring to FIG. 1, in process P11, a substrate is prepared.

The substrate may include silicon, a ceramic, glass, a metal, a metal nitride, or a combination thereof. The ceramic may include silicon nitride, titanium nitride, tantalum nitride, titanium oxide, titanium nitride, niobium oxide, zirconium oxide, hafnium oxide, lanthanum oxide, or a combination thereof. Each of the metal and the metal nitride may include, but is not limited to, Ti, Ta, Co, Ru, Zr, Hf, La, or a combination thereof. The surface of the substrate may have a planar shape, a spherical shape, a fiber shape, or a scalelike shape. In some implementations, the surface of the substrate may have a 3-dimensional structure, such as a trench structure.

In process P12 of FIG. 1, a ruthenium thin film may be deposited on the substrate by using a ruthenium compound represented by Chemical Formula 1 and/or Chemical Formula 2.

The ruthenium compound may include a ruthenium compound including hfac, for example. In some implementations, the ruthenium compound may include at least one of the ruthenium compounds represented by Formulae 1 to 28.

In some implementations, the ruthenium compounds represented by Chemical Formulae 8 to 12 instead of Chemical Formula 1 may be used, and/or the ruthenium compounds represented by Chemical Formulae 13 to 17 instead of Chemical Formula 2 may be used.

To form the ruthenium thin film according to process P12 of FIG. 1, a CVD process or an ALD process may be used. The ruthenium compound may be suitably used in a chemical deposition process, such as a CVD process or an ALD process. In some implementations, during the process of forming the ruthenium thin film, a reaction gas may be additionally supplied into a chamber. Examples of types and flow rates of the reaction gas are described below.

When the ruthenium compound is used in a CVD process, the composition of the ruthenium compound may be appropriately selected according to a transport method thereof. A raw material transport method includes a vapor transport method and a liquid transport method. In the vapor transport method, a raw material stored in a container (which may be referred to as a “raw material container”, hereinafter) may be changed into a vapor state by vaporizing the raw material through heating or decompression, and then, the raw material in the vapor state, together with a carrier gas such as argon, nitrogen, or helium, which may be used as needed, may be introduced into the chamber in which the substrate is placed. In the liquid transport method, a raw material may be transported in a liquid or solution state to a vaporization container, followed by changing the raw material into a vapor by vaporizing the raw material through heating and/or decompression in the vaporization container, and then, the vapor may be introduced into the chamber.

In some implementations, because the ruthenium compound includes an hfac ligand as described above, the ruthenium compound has a low melting point and excellent volatility, and thus, may exhibit suitable properties as a material for CVD or ALD processes when process P12 is performed.

In process P13, unnecessary by-products on the substrate may be removed by supplying a purge gas onto the substrate.

The purge gas may include, for example, an inert gas, such as Ar, He, or Ne, N₂ gas, or the like.

In some implementations, instead of the purge process, an exhaust process may be performed through the decompression of a reaction space in which the substrate is located. Here, for the decompression of the reaction space, the pressure of the reaction space may be maintained at about 0.01 Pa to about 300 Pa, for example, about 0.01 Pa to about 100 Pa, but the exhaust process is not limited thereto.

An example of a process, described with reference to FIG. 1, of forming the ruthenium thin film may be performed under the following conditions.
(1) Process temperature: 200° C. to 500° C.
(2) Flow rate of ruthenium compound supplied: 1 sccm to 200 sccm
(3) Type of reaction gas: NH₃, H₂, or a combination thereof, and/or an oxidative gas
(4) Flow rate of reaction gas supplied: 0 sccm to 4000 sccm
(5) Process pressure: 0.1 Torr to 100 Torr
(6) Deposition method of ruthenium: one of CVD, plasma-enhanced CVD (PECVD), ALD, and plasma-enhanced ALD (PEALD)

The process, described with reference to FIG. 1, of forming the ruthenium thin film is only an example and may be variously modified and changed without departing from the scope of this disclosure.

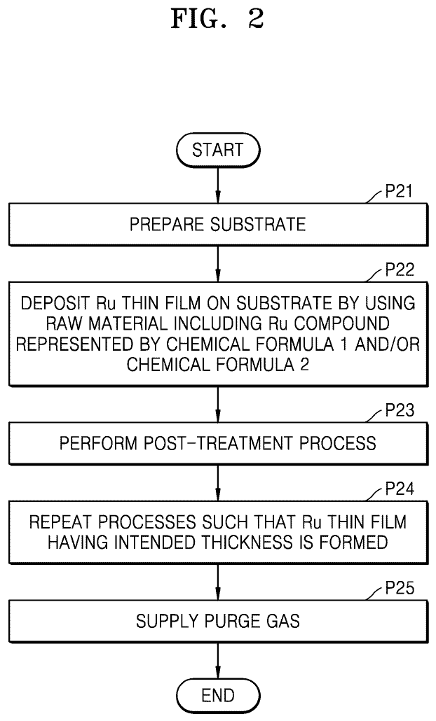

FIG. 2 is a flowchart illustrating an example of a method of forming a ruthenium thin film.

The flowchart of FIG. 2 is not mutually exclusive with the flowchart of FIG. 1. All the process conditions described with reference to FIG. 1 may also be applied to processes according to the flowchart of FIG. 2, and it will be understood that process P21, process P22, and process P25 of FIG. 2 respectively correspond to process P11, process P12, and process P13 of FIG. 1. Hereinafter, repeated descriptions of the processes corresponding to the processes of FIG. 1 are omitted, and differences from the flowchart of FIG. 1 are mainly described.

Referring to process P23 of FIG. 2, a post-treatment process may be performed on the ruthenium thin film that is formed on the substrate through process P21 and process P22.

Here, in process P22, as in process P12 of FIG. 1, the ruthenium compounds represented by Chemical Formulae 8 to 12 instead of Chemical Formula 1 may be used, and/or the ruthenium compounds represented by Chemical Formulae 13 to 17 instead of Chemical Formula 2 may be used.

Referring again to process P23, the post-treatment process may include performing a heat treatment for heating a reaction chamber, in which the substrate is accommodated, or the substrate, in which the ruthenium thin film is formed, or a plasma treatment process, under the same conditions as temperature and pressure conditions when the reaction gas (e.g., NH₃, H₂, or a combination thereof) is used.

In process P24, processes P22 and P23 of FIG. 2 are repeated such that the ruthenium thin film having an intended thickness is formed.

When a thin-film forming process, which includes a series of processes including process P22 and process P23, is taken as one cycle, the cycle may be repeated a plurality of times such that the ruthenium thin film having an intended thickness is formed. In some implementations, when the ruthenium thin film is formed, the reaction temperature, the reaction pressure, the deposition rate, and the like may be appropriately selected according to the intended thickness of the ruthenium thin film.

Next, the cycle is repeatedly performed, and then, process P25 of supplying a purge gas may be performed. Because process P25 of FIG. 2 corresponds to process P13 of FIG. 1, repeated descriptions thereof are omitted.

The process, described with reference to FIG. 2, of forming the ruthenium thin film is only an example and may be variously modified and changed without departing from the scope of this disclosure.

FIGS. 3, 4A, and 4B are schematic diagrams illustrating an example of a method of forming a ruthenium thin film.

Specifically, FIG. 3 is a schematic diagram before a ruthenium thin film is formed, FIG. 4A is a schematic diagram illustrating a result when a ruthenium thin film is formed in an oxidation condition by using, as a precursor, a ruthenium compound including no hfac ligand, and FIG. 4B is a schematic diagram illustrating a result when a ruthenium thin film is formed in a non-oxidation condition by using, as a precursor, a ruthenium compound including an hfac ligand.

Referring to FIG. 3, a substrate 110 including a conductive region 200 may be prepared. The substrate 110 may further include an insulating film 120, and at least a portion of the upper surface of the conductive region 200 may be exposed by a space in the insulating film 120.

In some implementations, the substrate 110 may include a semiconductor, such as Si or Ge, or a compound semiconductor, such as SiGe, SiC, GaAs, InAs, or InP. The conductive region 200 may include polysilicon, a metal, a conductive metal nitride, a metal silicide, or a combination thereof. In some implementations, the conductive region 200 may be connected to one terminal of a switching device (not shown), such as a field-effect transistor, which is formed afterwards on the substrate 110.

FIG. 4A shows a result when a ruthenium thin film 300 is formed according to the flowchart of FIG. 1 and/or FIG. 2 by using, as a precursor, a ruthenium compound including no hfac ligand and no hfac alternative discussed above. The ruthenium thin film 300 may be formed to fill the space in the insulating film 120, and thus, the exposed upper surface of the conductive region 200 may be covered by the ruthenium thin film 300.

Referring to FIG. 4A, as a result of using an oxidative gas (for example, one of O₂ gas, H₂O gas, and a combination thereof) as the reaction gas during the process of forming the ruthenium thin film, an oxide film 202 may be formed in an upper portion of the conductive region 200, that is, in the vicinity of the interface between the conductive region 200 and the ruthenium thin film 300. Because the oxide film 202 may cause deterioration in contact resistance with respect to other devices formed in processes after FIG. 4A, the oxide film 202 may adversely affect the reliability of the devices.

However, in some implementations, because a ruthenium compound including an hfac ligand (or hfac alternative discussed above) is used as a precursor, an oxidative gas is not required during the process of forming a thin film, and thus, such an issue described above may be solved.

FIG. 4B shows a result when the ruthenium thin film 300 is formed according to the flowchart of FIG. 1 and/or FIG. 2 by using, as a precursor, a ruthenium compound including an hfac ligand or an hfac alternative discussed above. The ruthenium thin film 300 may be formed to fill the space in the insulating film 120, and thus, the exposed upper surface of the conductive region 200 may be covered by the ruthenium thin film 300.

Referring to FIG. 4B, unlike in FIG. 4A, as a result of using a reductive gas (for example, one of O₂ gas, H₂O gas, and a combination thereof) as the reaction gas, it may be confirmed that an oxide film is not formed in the vicinity of the interface between the conductive region 200 and the ruthenium thin film 300. Accordingly, a ruthenium compound including an hfac ligand is used as a precursor for forming a ruthenium thin film, and thus, the ruthenium thin film including no impurity and having low resistivity may be formed, e.g., even in a non-oxidation condition.

Because FIGS. 3, 4A, and 4B are diagrams illustrated for convenience of description, the sizes and shapes of the substrate 110, the insulating film 120, the conductive region 200, the ruthenium thin film 300, and the like are only schematic.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A method of forming a thin film, the method comprising:
forming a ruthenium thin film by supplying a reaction gas and a precursor compound onto a first region of a substrate; and
supplying a purge gas onto the substrate,
wherein the precursor compound comprises a ruthenium compound that is:
represented by Chemical Formula 1 shown below, or
represented by Chemical Formula 1 in which CF₃ is replaced by CH₂F, CHF₂, CH₂Cl, CHCl₂, or CCl₃, and
wherein, in Chemical Formula 1, L¹ is a bidentate ligand.

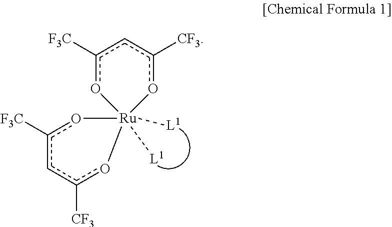

2. The method of claim 1, wherein L¹ is a diene.

3. The method of claim 2, wherein the diene is represented by Structural Formula 1 shown below, 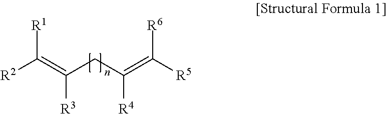
wherein, in Structural Formula 1, n is one of 0, 1, 2, 3, and 4, and each of R¹, R², R³, R⁴, R⁵, and R⁶ is hydrogen or a structure including carbon.

4. The method of claim 1, wherein L¹ is a diazadiene.

5. The method of claim 4, wherein the diazadiene is represented by Structural Formula 2 shown below, 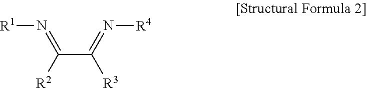
wherein, in Structural Formula 2, each of R¹ and R⁴ is a hydrocarbon, hydrogen, or a hydrocarbon including a heteroatom, and each of R² and R³ is hydrogen, carbon, or comprises a heteroatom.

6. The method of claim 1, wherein L¹ is an aminoether.

7. The method of claim 6, wherein the aminoether is represented by Structural Formula 3 shown below, 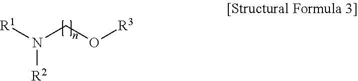
wherein, in Structural Formula 3, n is one of 1, 2, 3, and 4, and each of R¹, R², and R³ is hydrogen or a structure including carbon.

8. The method of claim 1, wherein L¹ is an allylamine.

9. The method of claim 8, wherein the allylamine is represented by Structural Formula 4 shown below, 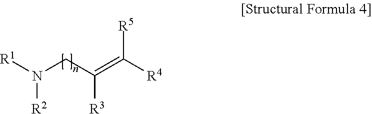
wherein, in Structural Formula 4, n is one of 1, 2, 3, and 4, and each of R¹, R², R³, R⁴, and R⁵ is hydrogen or a structure including carbon.

10. The method of claim 1, wherein the ruthenium compound is represented by Chemical Formula 1.

11. The method of claim 1, wherein the forming of the ruthenium thin film is performed by one selected from chemical vapor deposition (CVD), plasma-enhanced CVD (PECVD), atomic layer deposition (ALD), and plasma-enhanced ALD (PEALD).

12. The method of claim 1, wherein supplying the reaction gas and the precursor compound onto the first region of the substrate is repeated a plurality of times.

13. The method of claim 12, comprising performing a post-treatment process comprising a heat treatment or a plasma treatment between each repetition of the supplying of the reaction gas and the precursor compound.

14. A method of forming a thin film, the method comprising:
forming a ruthenium thin film by supplying a reaction gas and a precursor compound onto a first region of a substrate; and
supplying a purge gas onto the substrate,
wherein the precursor compound comprises a ruthenium compound that is:
represented by Chemical Formula 2 shown below, or
represented by Chemical Formula 2 in which CF₃ is replaced by CH₂F, CHF₂, CH₃Cl, CHCl₂, or CCl₃, and
wherein, in Chemical Formula 2, L² is a coordination ligand.

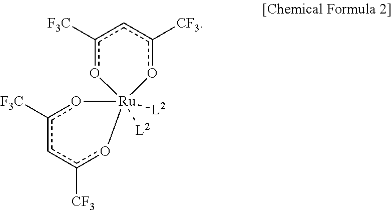

15. The method of claim 14, wherein L² is a nitrile represented by Structural Formula 5 shown below, and
in Structural Formula 5, R¹ comprises carbon.

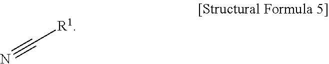

16. The method of claim 14, wherein the ruthenium compound is represented by Chemical Formula 2.

17. The method of claim 14, wherein the forming of the ruthenium thin film is performed by one selected from chemical vapor deposition (CVD), plasma-enhanced CVD (PECVD), atomic layer deposition (ALD), and plasma-enhanced ALD (PEALD).

18. The method of claim 14, wherein supplying the reaction gas and the precursor compound onto the first region of the substrate is repeated a plurality of times, and wherein the method further comprises performing a post-treatment process comprising a heat treatment or a plasma treatment between each repetition of the supplying of the reaction gas and the precursor compound.

19. A method of forming a thin film, the method comprising:
forming a ruthenium thin film by supplying at least one of a reductive reaction gas or an oxidative reaction gas, and a precursor compound, onto a first region of a substrate; and
supplying a purge gas onto the substrate,
wherein the precursor compound comprises at least one ruthenium compound from among ruthenium compounds represented by Chemical Formulae 1 to 12 shown below, 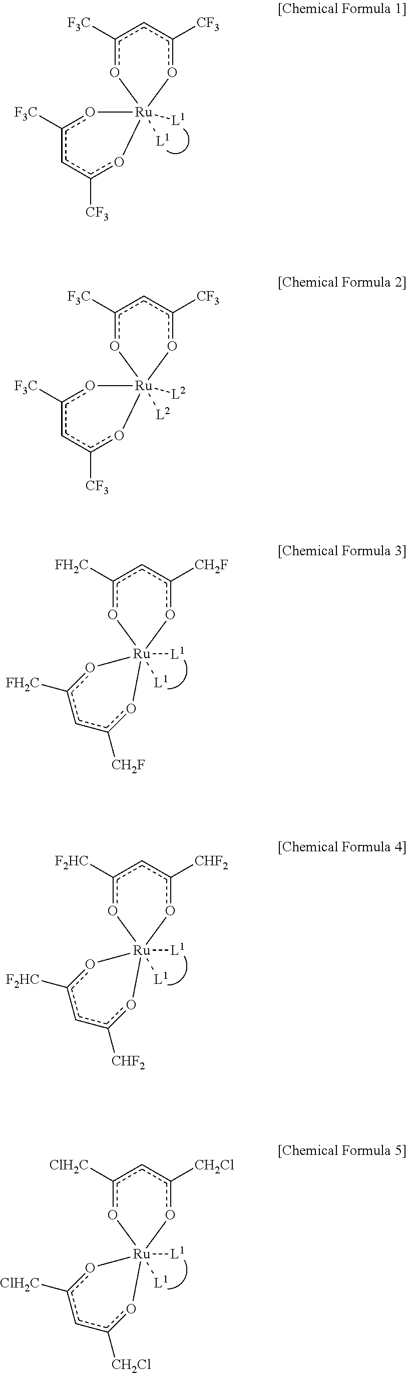 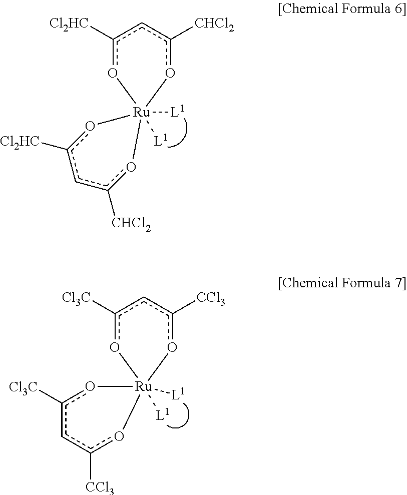 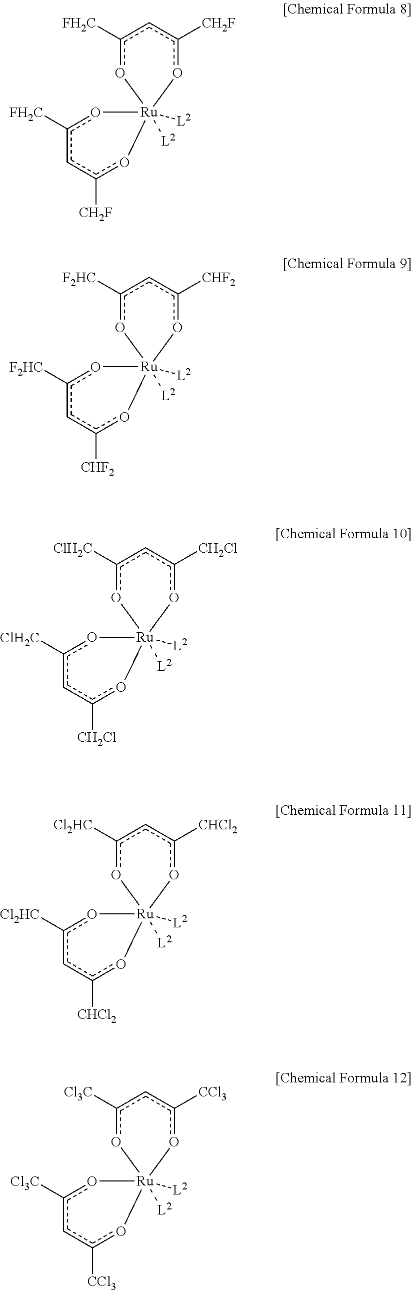
wherein, in Chemical Formulae 1, 3, 4, 5, 6, and 7, L¹ is a bidentate ligand, and
wherein Chemical Formulae 2, 8, 9, 10, 11, and 12, L² is a coordination ligand.

20. The method of claim 19, wherein supplying the least one of the reductive reaction gas or the oxidative reaction gas, and the precursor compound, is repeated a plurality of times, and
wherein the method further comprises performing a post-treatment process comprising a heat treatment or a plasma treatment between each repetition of the supplying of the least one of the reductive reaction gas or the oxidative reaction gas, and the precursor compound.
